(19) United States
(12) Patent Application Publication
(10) Pub. No.: US 2009/0067138 A1
(43) Pub. Date: Mar. 12, 2009

(54) SLIDER TYPE ELECTRONIC DEVICE

(75) Inventors: Mark W. Oliver, Mundelein, IL (US); Andrew P. Miehl, Sunrise, FL (US); Mitchell E. Goodman, Coral Springs, FL (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/853,246

(22) Filed: Sep. 11, 2007

(51) Int. Cl. H05K 5/00

(52) U.S. Cl. 361/730

(57) ABSTRACT

An electronic device is provided, which includes first housing, a first electronic element incorporated into the first housing, a second housing slidably coupled to the first housing, and a second electronic element incorporated into the second housing. A connective member couples the first electronic element to the second electronic element. The connective member includes a rolling flexible segment contained substantially within the first housing.

### FIELD OF THE INVENTION

The present invention relates generally to slider type electronic devices (e.g., mobile phones), and, more particularly, to signal routing between two housings of a slider type electronic device.

### BACKGROUND OF THE INVENTION

Various form factors have been developed for mobile phones, notably the bar or block type (generally characterized by a unitary monolithic housing), the clamshell type (generally characterized by two hingedly-coupled housings), and the flip type (generally characterized by a monolithic housing having a movable guard piece, which covers the phone's keypad and/or display when not in use). Another mobile phone form factor that has become relatively successful is the slider type. A slider type mobile phone includes a base housing and a slider housing, which is slidably coupled to the base housing and may move relative thereto between a closed position and an open position. At least one electronic element is incorporated into each housing. For example, a display (e.g., a liquid crystal display) and a user input (e.g., a navigation device) may be incorporated into the slider housing, and a numeric or alphanumeric keypad (e.g., a QWERTY keypad) may be incorporated into the base housing. In the closed position, the rear face of the slider housing resides adjacent (i.e., overlaps) the front face of the base housing. Thus, in the closed position, the slider housing covers the keypad and thus prevents the accidental actuation thereof. To transition to the open position and expose the keypad, a user may move the slider housing relative to the base housing by, for example, pushing upward on the slider housing while holding the base housing stationary.

In the open position, a lower portion of the slider housing overlaps with an upper portion of the base housing to accommodate a flexible circuit, which extends between the slider housing and the base housing to operatively couple the electronic element(s) disposed in both housings. In a conventional slider type mobile phone, a first end of the flexible circuit is attached to a connector provided on or within the base housing, and a second end of the flexible circuit is attached to a connector provided on or within the slider housing. The middle portion of the flexible circuit is not enclosed within either housing. Instead, the flexible circuit's middle portion resides substantially between the slider housing and the base housing. The flexile circuit's middle portion bends or rolls to permit relative movement between the flexible circuit's ends as the slider housing is moved relative to the base housing.

Due to the manner in which the above-described flexible circuit is routed between the base housing and the slider housings, the range of motion (i.e., travel) of the slider housing is relatively limited. Stated differently, in conventional slider type mobile phones, the base housing and the slider housing have a relatively wide overlap in the open position. This overlap is typically at least ⅓ of the total width or length of the phone (taken along the axis of motion). Such a wide overlap decreases the amount of surface area available on the base housing for the disposition of keypad (or other user inputs). As a result, it may be necessary to reduce the size of keypad and/or to increase the overall size of the mobile phone.

It should thus be appreciated that it is desirable to provide a slider type electronic device (e.g., a mobile phone) wherein the overlap between the base housing and the slider housing is relatively narrow in the open position. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

An electronic device is provided, which includes first housing, a first electronic element incorporated into the first housing, a second housing slidably coupled to the first housing, and a second electronic element incorporated into the second housing. A connective member couples the first electronic element to the second electronic element. The connective member includes a rolling flexible segment contained substantially within the first housing.

### BRIEF DESCRIPTION OF THE DRAWINGS

The present invention will hereinafter be described in conjunction with the following drawing figures, wherein like numerals denote like elements, and:

FIG. 1 is an isometric view of a conventional slider type mobile phone in an open position;

FIGS. 2, 3, and 4 are cross-sectional views of a slider type mobile phone in closed, intermediate, and open positions, respectively, in accordance with a first exemplary embodiment of the present invention;

FIG. 5 is an isometric view of an exemplary flexible circuit suitable for use as the elongated connective member employed in the slider type mobile phone shown in FIGS. 2-4;

FIGS. 6 and 7 are cross-sectional and exploded cutaway views, respectively, of a slider type mobile phone in a closed position in accordance with a second exemplary embodiment of the present invention; and

FIG. 8 is an isometric view of an exemplary flexible circuit suitable for use as the elongated connective member employed in the slider type mobile phone shown in FIGS. 6 and 7.

### DETAILED DESCRIPTION OF AT LEAST ONE EXEMPLARY EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

The following describes multiple exemplary embodiments of a slider type mobile phone; however, it is emphasized that the slider type form factor may be utilized in conjunction with a wide variety of portable electronic devices, including, but not limited to, personal digital assistants (PDAs), digital music players, handheld global position system (GPS) units, text messaging devices, and the like. Also, for the purposes of the following description, the term “electronic element” is intended in its broadest sense and may include any number of circuits, connectors, processors, memories, batteries, and other electronic components generally utilized to support an electronic device.

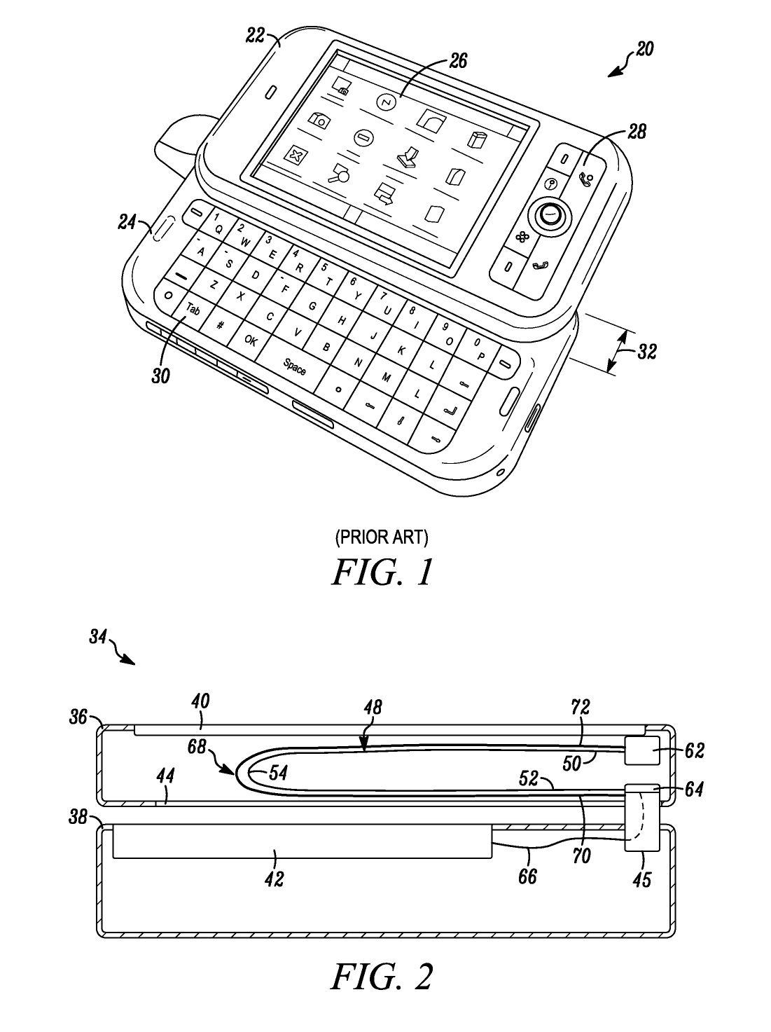

FIG. 1 is an isometric view of a conventional slider type mobile phone 20. Mobile phone 20 includes a slider housing 22 and a base housing 24, which are movably coupled together such that slider housing 22 may slide relative to base housing 24 between an open position (illustrated) and a closed position. At least one electronic element (e.g., display 26 and a cluster of user inputs 28) is incorporated into slider housing 22. Similarly, at least one electronic element (e.g., a QWERTY keypad 30) is incorporated into base housing 24. A flexible connective member (e.g., a flexible circuit), which is hidden from view in FIG. 1, extends between slider housing 22 and base housing 24 to electrically couple the electronic element(s) incorporated into slider housing 22 to those incorporated into base housing 24. When mobile phone 20 is in the open position, a portion of slider housing 22 overlaps with a portion base housing 24. As indicated in FIG. 1 at 32, this overlap is relatively wide and may be, for example, approximately ⅓ of the total width of phone 20 (as taken along the axis of motion).

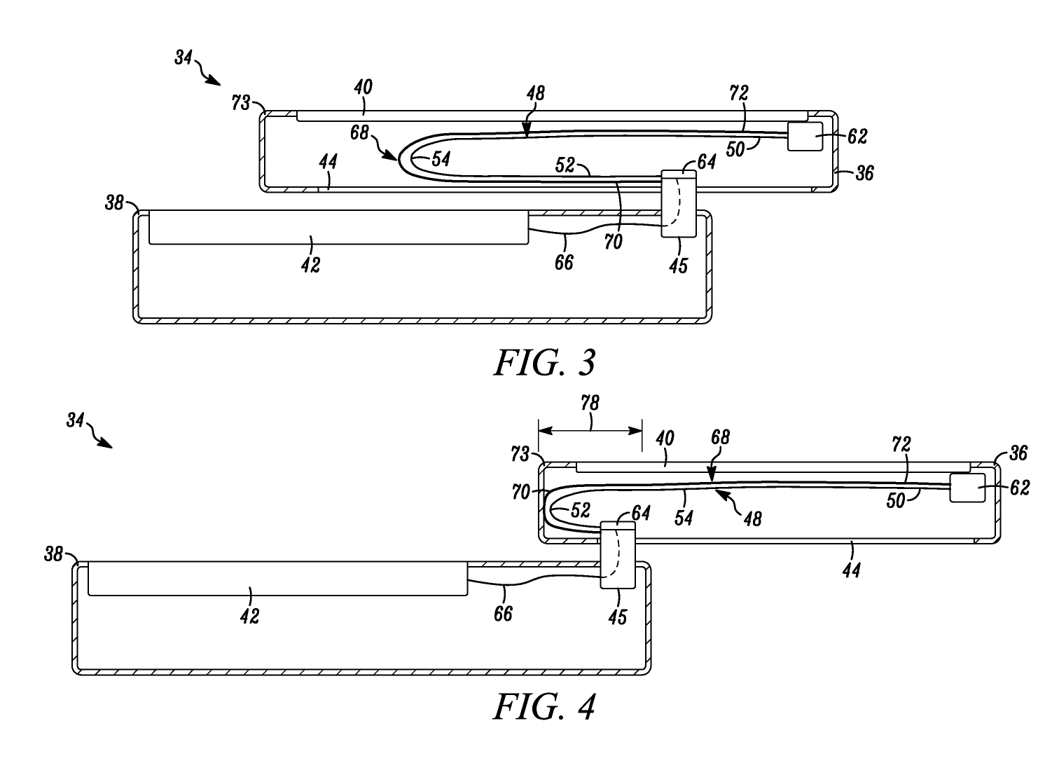

FIGS. 2-4 are simplified cross-sectional views of a slider type electronic device 34 in accordance with a first exemplary embodiment of the present invention. Electronic device 34 may be a slider type mobile phone and will consequently be referred to as such hereafter. As was the case previously, slider type mobile phone 34 includes a slider housing 36 and a base housing 38. Slider housing 36 is movably coupled to base housing 38 such that slider housing 36 may slide relative thereto between a closed position (shown in FIG. 2), an open position (shown in FIG. 4), and various intermediate positions (one of which is shown in FIG. 3). Again, at least one electronic element (e.g., a display 40) is incorporated into slider housing 36, and at least one electronic element (e.g., a keypad 42) is incorporated into base housing 38. Base housing 38 may also house various other known electronic components (e.g., a printed circuit board, a battery, etc.) that support the functioning of keypad 42 and/or display 40; however, these components are not shown in FIGS. 2-4 for clarity. In the closed position (FIG. 2), slider housing 36 resides substantially adjacent base housing 38 so as to substantially overlap with and protect keypad 42 and prevent the accidental actuation thereof. In the open position (FIG. 4), slider housing 36 is moved relative to base housing 38 to expose keypad 42 and thus permit user access thereto.

Slider housing 36 may be movably coupled to base housing 38 in any suitable manner; however, housings 36 and 38 are preferably coupled by way of at least one projection (e.g., a rail) disposed on one of the housings, which extends into and slides along a recess (e.g., a slot) formed in the other housing. For example, as shown in FIGS. 2-4, a projection 45 may be fixedly coupled to base housing 38 and extend therefrom. Projection 45 may be received within an open slot 44 provided through the rear face of slider housing 36. Projection 45 may travel within slot 44 as slider housing 36 is moved between its closed position (FIG. 2) and its open position (FIG. 4). If desired, slider housing 36 may be provided with one or more protective elements disposed proximate slot 44 to block debris from entering slider housing 36 through slot 44 when mobile phone 34 is in the open position. These protective elements may be, for example, a sealing member (e.g., a gasket or a polymeric flap). Alternatively, the protective elements may comprise a plurality of brushes.

Regardless of the particular manner in which slider housing 36 is coupled to base housing 38, an elongated connective member is utilized to couple the electronic element(s) incorporated into slider housing 36 to those incorporated into base housing 38. The elongated connective member includes first and second end portions, which may be fixedly coupled to slider housing 36 and base housing 38, respectively, as described more fully below. The elongated connective member also includes a flexible intermediate region or segment, which may roll as the first and second end portions move relative to one another. To this end, the elongated connective member may comprise any electrically conductive body that includes such a flexible rolling segment; e.g., the elongated connective member may comprise one or more wires or cables. This notwithstanding, the elongated connective member preferably comprises a flexible circuit. As appearing herein, the term “flexible circuit” is used in its broadest sense and includes any circuit wherein at least two of the circuit's end portions are permitted to move relative to one another so as to accommodate the movement of a slider type electronic device. A non-exhaustive list of suitable substrates includes various plastics (e.g., polyimide films), metal films, and epoxy resin bonded glass fabrics (e.g., Flame Resistant 4). The “flexible circuit” may be single layer or multilayer and, if desired, may include stiffeners (e.g., polyimide glass, polyimide, FR-4, and various metals, such as copper and aluminum). Furthermore, the “flexible circuit” may be a hybrid circuit (referred to as a “rigid flex circuit”) supported, in part, by a rigid substrate (e.g., epoxy glass, Flame Resistant 4, etc.).

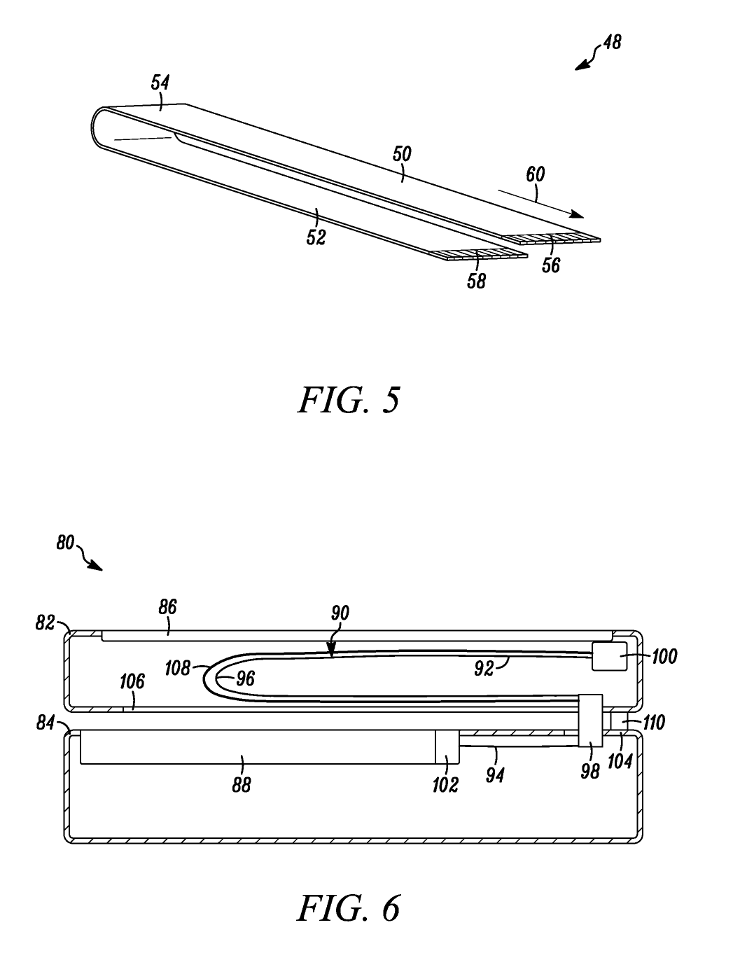

FIG. 5 is an isometric view of a flexible circuit 48 that may be disposed within mobile phone 34 (FIGS. 2-4) to electrically couple display 40 to keypad 42. Flexible circuit 48 includes a first end portion 50, a second end portion 52 substantially opposite first end portion 50, and an intermediate segment 54. A first plurality of contacts 56 may be provided on first end portion 50, and a second plurality of contacts 58 may be provided on second end portion 52. Intermediate segment 54 is flexible and may roll as end portion 52 is moved relative to end portion 50 in the manner indicated by arrow 60.

Referring once again to FIGS. 2-4, first end portion 50 of flexible circuit 48 may be fixedly coupled (e.g., via a hold down hook) to a connector 62 associated with display 40, and contacts 56 may be electrically coupled (e.g., via soldering, brazing, crimping, etc.) to a set of contacts (not shown) provided on connector 62. Similarly, second end portion 52 may be fixedly coupled (e.g., via a hold down hook) to a connector 64 associated with keypad 42, and contacts 58 may be electrically coupled to a set of contacts (not shown) provided on connector 64. In the illustrated exemplary embodiment, connector 64 is mounted on projection 45 and electrically coupled to keypad 42 via conductive pathway 66 (e.g., a cable), which extends through projection 45 and into base housing 38.

As slider housing 36 is moved relative to base housing 38, connector 62 and end portion 50 move relative to connector 64 and end portion 52. For example, end portion 50 may reside substantially adjacent end portion 52 in the closed position (FIG. 2), and end portion 50 may be offset from end portion 52 in the open position (FIG. 4). As slider housing 36 is moved between open and closed positions, flexible intermediate segment 54 rolls to accommodate the relative movement of end portions 50 and 52 and, therefore, the relative movement between slider housing 36 and base housing 38. By employing a connective member (e.g., flexible circuit 48) including a rolling flexible region (e.g., intermediate segment 54) that is substantially contained within one housing (e.g., slider housing 36) of slider type mobile phone 34, the overlap between slider housing 36 and base housing 38 in the open position may be minimized as generally indicated in FIG. 4 by arrow 78.

In the illustrated exemplary embodiment, a roll guide member 68 is provided within slider housing 36 proximate (e.g., adjacent) flexible circuit 48. Roll guide member 68 may comprise any body or element suitable for guiding the movement of flexible intermediate segment 54; however, roll guide member 68 preferably comprises a strip of flexible material (e.g., polymeric film, sheet metal, etc.), which at least partially surrounds flexible circuit 48 and which may flex along therewith. In at least some instances, roll guide member 68 does not participate with the signal routing of flexible circuit 48 (e.g., roll guide member 68 may be electrically isolated from flexible circuit 48). Roll guide member 68 preferably circumscribes flexible circuit 48, including intermediate segment 54, in the manner shown in FIGS. 2-4. Roll guide member 68 includes first and second end portions 70 and 72. End portion 70 may be fixedly coupled to projection 45 (e.g., via a hold down hook), and end portion 72 may be fixedly coupled to connector 62 (e.g., also via a hold down hook). As slider housing 36 is moved between the closed position (FIG. 2) and the open position (FIG. 4), roll guide member 68 rolls along with flexible circuit 48. In so doing, roll guide member 68 guides the movement of flexible intermediate segment 54 to prevent the buckling thereof. In addition, roll guide member 68 significantly reduces friction between flexible circuit 48 and the other components of mobile phone 34 (e.g., housings 36 and 38) and thereby protects flexible circuit 48 from excess wear due to abrasion.

The foregoing has thus described an exemplary embodiment wherein end portions 70 and 72 of roll guide member 68 are fixedly attached to projection 46 and connector 62, respectively. This example notwithstanding, it should be understood that end portions 70 and 72 may instead be coupled to other structures internal to slider housing 36. For example, end portion 70 and/or end portion 72 may be attached (e.g., via lamination) to a neighboring end portion of flexible circuit 48. Alternatively, end portion 70 may be attached to projection 70 and/or flexible circuit 48, and end portion 72 may be free floating. In this latter case, roll guide member 68 may comprise a J-shaped body that flexes along with flexible circuit 48 when contacted by a lower wall 73 of slider housing 36.

In the above-described exemplary embodiment, the rolling flexible region (i.e., intermediate segment 54) of the connective member (i.e., flexible circuit 48) is contained within the slider housing; however, it should be appreciated that, in alternative embodiments, the rolling flexible segment may instead be contained within the base housing. Also, in alternative embodiments, the flexible circuit's first end portion may reside within the slider housing, while the circuit's second end portion resides in the base housing. In this case, the flexible circuit may include a bridge portion, which extends between the slider housing and the base housing as described more fully below in conjunction with FIGS. 6-8. As noted above, by employing a connective member including a rolling flexible region that is substantially contained within one housing of a slider type mobile phone (or other such electronic device), the overlap between the two housings in the open position may be minimized.

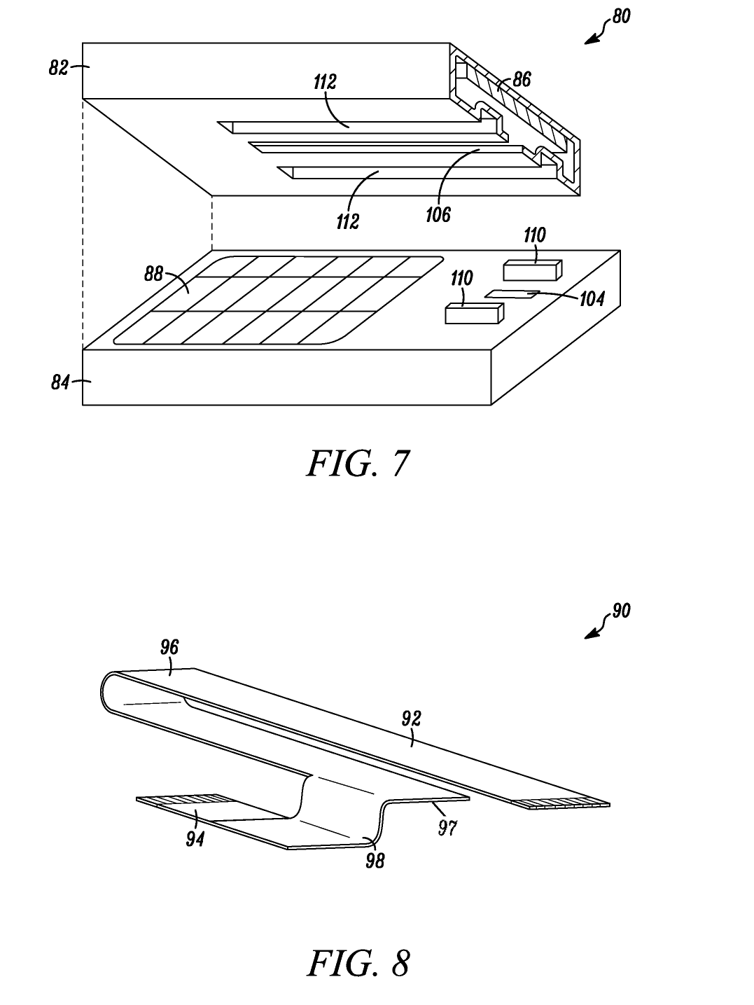

FIGS. 6 and 7 are cross-sectional and exploded views of a slider type electronic device (e.g., a mobile phone) 80 in accordance with a second exemplary embodiment of the present invention. Mobile phone 80 is similar to mobile phone 34 described above in conjunction with FIGS. 2-4; e.g., mobile phone 80 includes a slider housing 82 (shown in cutaway), which is slidably coupled to a base housing 84 and may move relative thereto between a closed position (illustrated) and an open position. At least a first electronic element (e.g., a display 86) is incorporated into slider housing 82, and at least a second electronic element (e.g., a keypad 88) is incorporated into base housing 84. As was the case previously, display 86 is electrically coupled to keypad 88 by way of an elongated flexible member. For example, display 86 may be electrically coupled to keypad 88 via a flexible circuit, such as flexible circuit 90 shown in FIG. 8. Flexible circuit 90 includes a first end portion 92, a second end portion 94, a flexible intermediate segment 96, and a bridge portion 98. It should also be noted that flexible intermediate segment 96 includes first and second end portion, which may or may not correspond to end portions of flexible circuit 90; e.g., flexible intermediate segment 96 may have a first end portion, which corresponds to first end portion 92 of flexible circuit 90, and a second end portion 97, which is distinct from end portion 94. As indicated in FIG. 6, first end portion 92 of flexible circuit 90 may be coupled to a first connector 100 associated with display 86 and disposed within slider housing 82. Similarly, second end portion 94 may be coupled to a second connector 102 associated with keypad 88 and disposed within base housing 84. When mobile phone 80 is assembled, bridge portion 98 extends between the housings of mobile phone 80 to connect end portion 92 to end portion 94, which reside within slider housing 82 and base housing 84, respectively. In particular, bridge portion 98 extends through open slot 106 provided through slider housing 82 and into an aperture 104 provided through base housing 84. If desired, one or more protective elements (e.g., a gasket, a plurality of brushes, etc.) may be disposed proximate open slot 106 (e.g., extend inwardly from each longitudinal edge of open slot 106) to help prevent debris from entering slider housing 82 in the open position.

As slider housing 82 is moved between the closed position (FIGS. 6 and 7) and the open position, bridge portion 98 and end portion 94 remain substantially stationary. In contrast, end portion 92 moves along with connector 100 and slider housing 82. Flexible intermediate segment 96 rolls to accommodate the relative movement of end portions 92 and 94. A flexible roll guide 108 (FIG. 6) may be provided within slider housing 82 to guide the movement of intermediate segment 96. One end of flexible roll guide 108 (FIG. 6) may be coupled to flexible circuit 90 (e.g., bridge portion 98) by way of, for example, lamination. The opposite end of flexible roll guide member 108 (FIG. 6) may be coupled to connector 100 (e.g., via a hold down hook). If desired, a slide guide assembly may be provided on slider housing 82 and/or base housing 84 to guide the movement of slider housing 82. For example, one or more toothed wheels may be rotatably mounted on the front face of base housing 84 (or on the rear face of slider housing 82) and engage a toothed track formed in the rear face of slider housing 82 (or in front face of base housing 84). Alternatively, one or more projections may extend from base housing 84 (or from slider housing 82) into one or more slots provided in slider housing 82 (or in base housing 84). For example, as most clearly shown in FIG. 7, first and second projections 110 may extend from the front face of base housing 84 and into first and second closed slots 112 formed in the rear face of slider housing 82. As slider housing 82 is moved between its open and closed positions, projections 110 travel within slots 112 to provide a smooth and controlled sliding motion.

It should thus be appreciated that there has been provided at least two examples of a slider type portable electronic device (e.g., a mobile phone) wherein the overlap between the base housing and the slider housing is relatively narrow in the open position. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. An electronic device, comprising:
a first housing;
a first electronic element incorporated into the first housing;
a second housing slidably coupled to the first housing;
a second electronic element incorporated into the second housing; and
a connective member coupling the first electronic element to the second electronic element, the connective member including a rolling flexible segment contained substantially within the first housing.

2. An electronic device according to claim 1 wherein the first housing is a slider housing, and the second housing is a base housing.

3. An electronic device according to claim 1 wherein the connective member comprises a flexible circuit.

4. An electronic device according to claim 1 wherein the connective member includes a first end portion and a second end portion substantially opposite the first end portion, the first end portion residing within the first housing.

5. An electronic device according to claim 4 wherein the rolling flexible segment is disposed between the first end portion and the second end portion.

6. An electronic device according to claim 4 wherein the second end portion resides within the first housing.

7. An electronic device according to claim 6 further comprising a projection extending from the second housing into the first housing, the second end portion coupled to the projection.

8. An electronic device according to claim 7 wherein the first housing includes an open slot, the projection extending into the open slot and traveling therein as the first housing is moved relative to the second housing.

9. An electronic device according to claim 4 wherein the second end portion resides within the second housing.

10. An electronic device according to claim 9 wherein the connective member includes a bridge portion extending between the first housing and the second housing.

11. An electronic device according to claim 1 further comprising a roll guide member disposed within the first housing proximate the connective member, the roll guide member guiding the movement of the rolling flexible segment.

12. An electronic device according to claim 11 wherein the roll guide member comprises a flexible strip at least partially disposed around the connective member.

13. An electronic device according to claim 12 wherein the roll guide member substantially circumscribes the rolling flexible segment.

14. An electronic device according to claim 11 further comprising a connector disposed within the first housing and electrically coupling the connective member to the first electronic element, the roll guide member fixedly coupled to the connector.

15. An electronic device, comprising:
a base housing;
a first electronic element incorporated into the base housing;
a slider housing slidably coupled to the base housing and movable between an open position and a closed position;
a second electronic element incorporated into the slider housing; and
an elongated connective member, comprising:
a first end portion coupled to the first electronic element;
a second end portion coupled to the second electronic element, the second end portion residing substantially adjacent the first end portion when the slider housing is in the closed position; and
a flexible intermediate segment configured to roll to accommodate relative movement between the first end portion and the second end portion as the slider housing is moved between the open position and the closed position.

16. An electronic device according to claim 15 wherein the elongated connective member is substantially contained within the slider housing.

17. An electronic device according to claim 15 wherein the elongated connective member comprises a flexible circuit.

18. An electronic device according to claim 16 further comprising a roll guide member disposed in the slider housing proximate the elongated connective member.

19. An electronic device, comprising:
a first housing;
a first electronic element incorporated into the first housing;
a second housing slidably coupled to the first housing and movable between an open position and a closed position;
a second electronic element incorporated into the second housing; and
a flexible circuit coupling the first electronic element to the second electronic element, the flexible circuit including a rolling flexible segment contained substantially within the first housing; and
a rolling guide member disposed within the first housing and configured guide the movement of the flexible circuit as the second housing is moved between the open position and the closed position.

20. An electronic device according to claim 19 wherein the first housing is a base housing, and the second housing is a slider housing.
